(19) United States
(12) Patent Application Publication
(10) Pub. No.: US 2016/0111554 A1
(43) Pub. Date: Apr. 21, 2016

(54) SEMICONDUCTOR DEVICE

(71) Applicant: KABUSHIKI KAISHA TOSHIBA, Tokyo (JP)

(72) Inventors: Yoshimitsu KUWAHARA, Nonoichi Ishikawa (JP); Hideaki KITAZAWA, Kamakura Kanagawa (JP); Eitaro MIYAKE, Kawasaki Kanagawa (JP)

(21) Appl. No.: 14/831,744

(22) Filed: Aug. 20, 2015

(30) Foreign Application Priority Data
Oct. 17, 2014 (JP) 2014-213095

(51) Int. Cl. H01L 29/84; H01L 21/54; H01L 23/06; H01L 25/07; H01L 29/739

(52) U.S. Cl. CPC H01L 29/84; H01L 25/072; H01L 29/7393; H01L 23/06; H01L 21/54

(57) ABSTRACT

A semiconductor device, such as a pressure contact type semiconductor device, includes a frame body comprising ceramic and having an annular cylindrical shape which satisfies a relationship: (2/5E)·(D/t)³≦17.4, when the inner diameter of the frame body is D (in mm), the thickness of the frame body in a radial direction is t (in mm), and the Young's modulus of the ceramic is E (in GPa). A plurality of semiconductor elements are enclosed within an interior spaced formed by at least the frame body, a first electrode block disposed on one side of the semiconductor elements, and a second electrode block disposed on another side of the semiconductor elements.

### CROSS-REFERENCE TO RELATED APPLICATION

This application is based upon and claims the benefit of priority from Japanese Patent Application No. 2014-213095, filed Oct. 17, 2014, the entire contents of which are incorporated herein by reference.

### FIELD

An embodiment described herein relates to a semiconductor device.

### BACKGROUND

A pressure contact type semiconductor device achieves an enhancement in power density by using double-sided heat dissipation and provides high reliability even when operating at a high voltage and with a large current. The pressure contact type semiconductor device has the structure in which a semiconductor element that is disposed in an insulating frame body, which is between upper and lower electrode blocks is hermetically sealed. By applying a pressing force to the upper and lower electrode blocks from the outside, an electrical contact in the semiconductor device is maintained.

However, when a part of the semiconductor element disposed in pressure contact type semiconductor device is broken, short-circuiting occurs without causing the breaking of the semiconductor device per se. Accordingly, by using the pressure contact type semiconductor device in a mode where the pressure contact type semiconductor devices are connected in series, the pressure contact type semiconductor device may acquire an advantageous effect that operational redundancy may be easily provided. For example, the semiconductor device may be operated without instantaneously stopping a system even after a particular semiconductor element within the semiconductor device is broken.

However, when an excessively large load state continues in the broken semiconductor element, the semiconductor element is melted due to a remarkable temperature elevation, thus an internal pressure of the semiconductor element may increase resulting in the explosion. When the explosion occurs, broken pieces of the semiconductor device scatter, and this can damage a circuit or a cooling device provided in proximity to the semiconductor device, thus a system may become inoperable.

### DESCRIPTION OF THE DRAWINGS

FIG. 1A and FIG. 1B are schematic views of a semiconductor device according to an embodiment.

FIG. 2A and FIG. 2B are schematic views of a housing used in the embodiment.

FIG. 3 is a graph showing the operational results of various examples and a comparison example.

### DETAILED DESCRIPTION

According to an embodiment, there is provided a pressure contact type semiconductor device which may suppress the breaking of a semiconductor element.

In general, according to one embodiment, a semiconductor device includes: a frame body formed of a material containing ceramic, having an annular cylindrical shape, and satisfying a following formula (Formula 1):

(2/5E)·(D/t)³≦17.4 (1)

where an inner diameter of the frame body is D (mm), a thickness of the frame body in a radial direction is t (mm), and Young's modulus of the ceramic is E (GPa); a plurality of semiconductor elements disposed in an interior space formed by at least the frame body, a first electrode block disposed on a first side of the semiconductor elements, and a second electrode block disposed on a second side of the semiconductor elements.

In this disclosure, “ceramic” includes in its meaning a sintered body obtained by sintering an inorganic substance.

Hereinafter, an example embodiment is explained by reference to drawings. In the explanation made hereinafter, identical members are given the same symbol, and the repeated explanation of members which are explained once is omitted when appropriate.

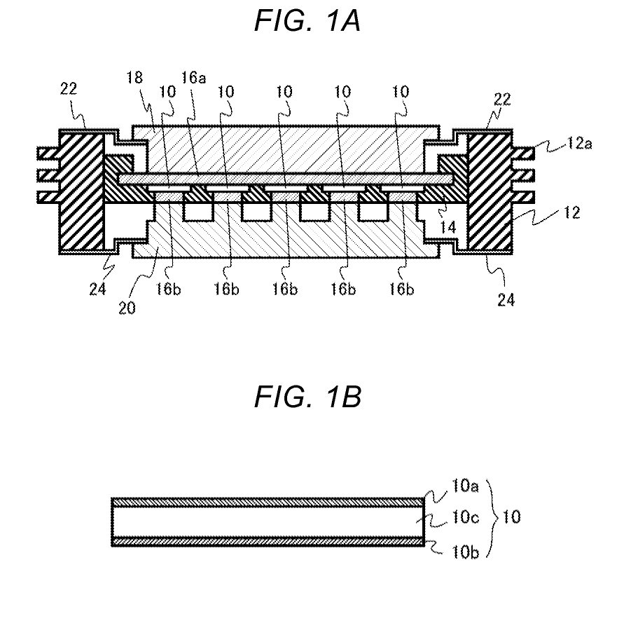

FIG. 1A and FIG. 1B are schematic views of the semiconductor device according to the first embodiment. FIG. 1A is a schematic cross-sectional view of the semiconductor device, and FIG. 1B is a schematic cross-sectional view of a semiconductor element included in the semiconductor device depicted in FIG. 1A. The semiconductor device according to this first embodiment is a pressure contact type semiconductor device. The semiconductor device according to this embodiment is a PPI (Press Pack IEGT (injection-enhanced gate transistor)), for example.

In the semiconductor device according to the first embodiment, a plurality of semiconductor elements 10 is disposed in the inside (an interior space) of the semiconductor device. As shown in FIG. 1B, the semiconductor element 10 includes: a first electrode 10a formed on a first surface and a second electrode 10b formed on a second surface on a side opposite to the first surface. A semiconductor element region 10c is disposed between the first electrode 10a and the second electrode 10b.

The semiconductor element 10 is an IEGT (Injection Enhanced Gate Transistor) formed of silicon (Si), for example. The IEGT is an IGBT (Insulated Gate Bipolar Transistor) having an electron injection enhancing effect. The first electrode 10a forms an emitter electrode, for example. The second electrode 10b forms a collector electrode, for example. The semiconductor element 10 includes a gate electrode not shown in the drawing.

The semiconductor element 10 is not particularly limited to being an IEGT and may be another device type provided that the semiconductor element 10 is a device having electrodes on upper and lower surfaces thereof. For example, the semiconductor element 10 may be a diode such as an FRD (Fast Recovery Diode). The semiconductor element 10 may be a MOSFET (Metal Oxide Semiconductor Field Effect Transistor). Also, more than one device type may be incorporated as semiconductor elements 10, for example, both an IEGT and an FRD may be mounted on the semiconductor device together as semiconductor elements 10. Further, the semiconductor elements 10 are not limited to a device formed of silicon, and may be formed of silicon carbide (SiC), for example.

The semiconductor elements 10 are disposed in an insulating frame body (also referred to as “housing”) 12. Here, the housing 12 has an annular shape and is formed of ceramic. The housing 12 has an annular cylindrical shape, for example. The housing 12 includes projecting portions (exterior ridges) 12a for maintaining electrical separation (a creepage distance) between the first electrode 10a and the second electrode 10b, for example.

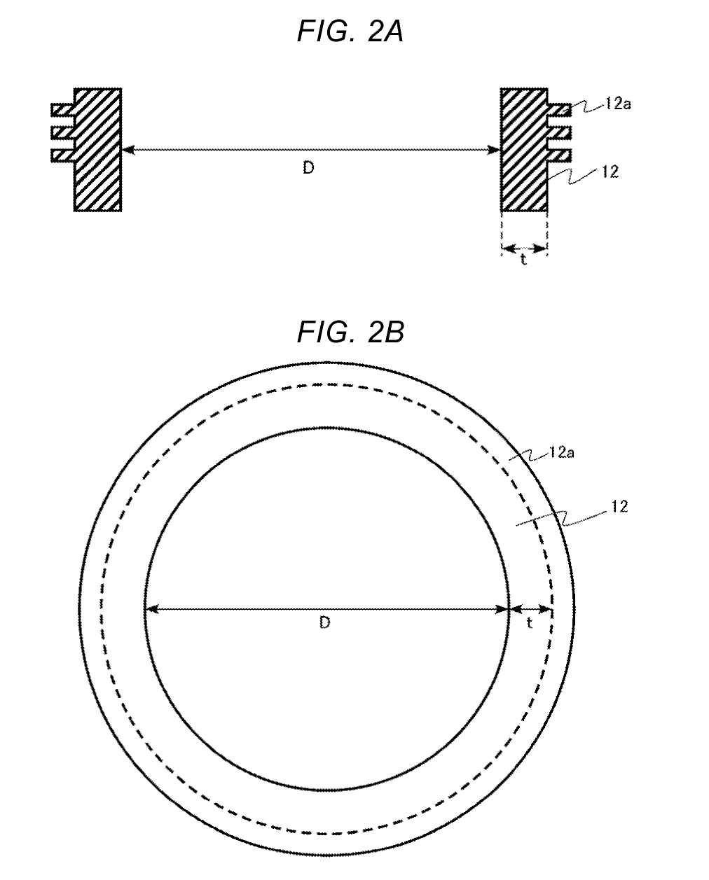

FIG. 2A and FIG. 2B are schematic views of the housing 12 according to the first embodiment. FIG. 2A is a cross-sectional view of the housing 12, and FIG. 2B is a top plan view of the housing 12.

Assuming that an inner diameter of the housing 12 is D (in mm), a thickness of the housing 12 in the radial direction is t (in mm), and Young's modulus of the ceramic of the housing 12 is E (in GPa), the housing 12 satisfies the following formula (1):

(2/5E)·(D/t)³≦17.4 (1)

It is more preferable that the housing 12 satisfy the following formula (2):

(2/5E)·(D/t)³≦4.8 (2)

As shown in FIG. 2, the thickness of the housing 12 in the radial direction is a thickness of portions of the housing 12 excluding the projecting portions 12a. That is, the length of the projecting portions 12a along the radial direction are not included in the thickness (t) of the housing 12 in the above equations.

In general, it is preferable that the thickness (t) of the housing 12 in the radial direction be set to 10 mm or more.

The housing 12 is formed of alumina, for example. It is also possible to use other materials such as silicon nitride, zirconia, aluminum nitride or the like as a material for forming the housing 12 besides alumina, for example.

The plurality of semiconductor elements 10 are supported by a resin frame 14. The resin frame 14 can be used to align the plurality of semiconductor elements 10 so as to ensure an appropriate insulation distance between termination regions of semiconductor elements.

A heat compensating plate 16a is formed on a first surface side of the semiconductor elements 10, and heat compensating plates 16b are formed on a second surface side of the semiconductor elements 10. A material having a thermal expansion coefficient close to a thermal expansion coefficient of the semiconductor element 10 is typically used as a material for forming the heat compensating plate 16a and the heat compensating plates 16b. For example, when the semiconductor element 10 is formed of silicon, molybdenum having a thermal expansion coefficient close to a thermal expansion coefficient of silicon is used as a material for forming the heat compensating plate 16a and the heat compensating plates 16b.

A first electrode block 18 is disposed on a first surface side of the semiconductor elements 10. A second electrode block 20 is disposed on a second surface side of the semiconductor elements 10. The first electrode block 18 and the second electrode block 20 have a circular shape when viewed from a direction orthogonal to the first or second surface of the semiconductor elements 10, for example.

The first electrode block 18 is disposed in contact with the heat compensating plate 16a. The second electrode block 20 is disposed in contact with the heat compensating plate 16b. The first electrode block 18 and the second electrode block 20 are made of metal, for example, copper.

The first electrode block 18 and the housing 12 are connected to each other by a first flange 22. The first flange 22 is made of metal, for example, a nickel-iron alloy.

The first electrode block 18 and the first flange 22 are connected to each other by welding, for example. The first flange 22 and the housing 12 are connected to each other by brazing, for example.

The second electrode block 20 and the housing 12 are connected to each other by a second flange 24. The second flange 24 is made of metal, for example, a nickel-iron alloy.

The second electrode block 20 and the second flange 24 are connected to each other by welding, for example. The second flange 24 and the housing 12 are connected to each other by brazing, for example.

The housing in which the semiconductor elements 10 are disposed is hermetically sealed using the combination of the housing 12, the first electrode block 18, the second electrode block 20, the first flange 22 and the second flange 24. An inert gas, for example, a nitrogen gas is filled in the inside of the housing. By filling the inert gas in the inside of housing of the semiconductor elements 10, it is possible to prevent the oxidization of the semiconductor elements 10, the heat compensating plate 16a, the heat compensating plates 16b and the like disposed in the inside of the device housing.

The first flange 22 and the second flange 24 are formed of a plate-shaped metal (e.g., a metal sheet), for example, and has a spring characteristic with proper strength. Accordingly, when a pressing force is applied to the first electrode block 18 and the second electrode block 20 from the outside, the semiconductor elements 10, the heat compensating plate 16a, the heat compensating plates 16b, the first electrode block 18, and the second electrode block 20 are brought into close contact with each other so that a favorable electric contact may be maintained. Accordingly, the first electrode block 18 becomes electrically connected with the first electrode 10a, and the second electrode block 20 becomes electrically connected with the second electrode 10b.

Next, the manner of operation and advantageous effects of the semiconductor device according to this first embodiment are explained.

For example, when an overload state continues after a semiconductor element 10 is broken (or becomes non-operational) and is short-circuited due to the applying of an overcurrent to the semiconductor element 10, the semiconductor element 10 may melt due to a temperature elevation, thus the sealed semiconductor device housing may explode or rupture. If an explosion occurs, a housing 12 and the like are broken so that pieces scatter. These broken pieces can damage a circuit and/or a cooling device around or adjacent to the semiconductor device, thus a larger system in which the semiconductor device has been incorporated may become inoperable due to failure of a single semiconductor element 10.

According to the present disclosure the explosion of the sealed semiconductor device may be suppressed by setting an inner diameter D of the housing, a thickness t of the housing and Young's modulus E such that a deformation amount of the housing 12 falls within a predetermined range. That is, the present disclosure establishes that the explosion of the semiconductor device may be suppressed when the following formula (1) is satisfied assuming that the inner diameter of the housing 12 is D (in mm), the thickness of the housing 12 in the radial direction is t (in mm), and Young's modulus of ceramic in the housing 12 is E(in GPa).

(2/5E)·(D/t)³≦17.4 (1)

Assuming that a deformation amount of the housing 12 is “v” when a force “F” acts on a point of the annular housing 12 (due to melting of the semiconductor element 10 or the like), then deformation amount v of the housing 12 may be approximated using the deformation amount from a cantilever model.

Then, when a force applied to one end of the cantilever is “F”, a deformation amount (displacement) of a point at which the force “F” is applied is “v”, a length of the cantilever is “L”, Young's modulus of the cantilever is “E”, and a geometrical moment of inertia is “I”, the deformation amount v may be expressed by the following formula (3):

v=FL³/3EI (3)

In this first embodiment, with respect to the annular housing 12, assuming that “L” in the formula (3) is the inner diameter D of the housing 12 and further assuming that “F” is a fixed value of 1. Then, the formula (3) may be modified to the following formula (4):

v=D³/3EI (4)

Assuming that a width of the cantilever is b (in mm), and a height of the cantilever in the direction along which the force is applied is h (in mm), the geometrical moment of inertia I may be expressed by the following formula (5):

I=bh³/12 (5)

In first embodiment, assuming that one region of the annular housing 12 is cut out, “b” in the formula (5) can be set to a fixed value of 10, and “h” is the thickness t. Then, the formula (5) may be modified to the following formula (6):

I=5t³/6 (6)

The following formula (7) may be derived from the formula (4) and the formula (6).

v=(2/5E)·(D/t)³ (7)

The present disclosure states that, based on experiment, by setting a value of “v” in the formula (7) to 17.4 or less, the explosion of the semiconductor device may be suppressed. Accordingly, the explosion of the semiconductor device may be suppressed when formula (1) is satisfied.

(2/5E)·(D/t)³≦17.4 (1)

Furthermore, by taking into account typical irregularities in working the housing 12 or the like, it is preferable from a viewpoint of suppressing an explosion, that the following formula (2) be satisfied.

(2/5E)·(D/t)³≦4.8 (2)

### EXAMPLES

Device examples and a comparison example are described hereinafter.

### Example 1

An electric current is supplied to a PPI where a plurality of IEGTs are disposed in the inside of the PPI under a condition that an IEGT disposed in the inside of the PPI is melted. A housing of the PPI is made of alumina having Young's modulus of 280 GPa. The housing has an annular cylindrical shape. An inner diameter D of the housing is set to 108.1 mm, and a thickness t of the housing in the radial direction is set to 4.7 mm. After an electric current is supplied to the PPI, it was checked whether or not the housing of the PPI has been broken.

### Example 2

A test was performed on the example 2 in the substantially same manner as the test performed on the example 1 except an inner diameter D of the housing is set to 98.6 mm, and a thickness t of the housing in the radial direction is set to 10 mm.

### Example 3

A test was performed on the example 3 in the substantially same manner as the test performed on the example 1 except an inner diameter D of the housing is set to 108.1 mm, and a thickness t of the housing in the radial direction is set to 10 mm.

### Example 4

A test was performed on the example 4 in the substantially same manner as the test performed on the example 1 except an inner diameter D of the housing is set to 98.6 mm, and a thickness t of the housing in the radial direction is set to 15 mm.

### Example 5

A test was performed on the example 5 in the substantially same manner as the test performed on the example 1 except an inner diameter D of the housing is set to 138.6 mm, and a thickness t of the housing in the radial direction is set to 10 mm.

### Example 6

A test was performed on the example 6 in the substantially same manner as the test performed on the example 1 except an inner diameter D of the housing is set to 149.4 mm, and a thickness t of the housing in the radial direction is set to 10 mm.

### Example 7

A test was performed on the example 7 in the substantially same manner as the test performed on the example 1 except an inner diameter D of the housing is set to 138.6 mm, and a thickness t of the housing in the radial direction is set to 15 mm.

### COMPARISON EXAMPLE

A test was performed on the comparison example in the substantially same manner as the test performed on the example 1 except an inner diameter D of the housing is set to 138.6 mm, and a thickness t of the housing in the radial direction is set to 4.7 mm.

Conditions and results of the examples 1 to 7 and the comparison example are summarized in Table 1.

TABLE 1

| | Inner | Thickness | | |
|---|---|---|---|---|
| | diameter (D) | (t) | (2/5E) · (D/t)³ | Breakage |
| Example 1 | 108.1 | 4.7 | 17.4 | not present |
| Example 2 | 98.6 | 10 | 1.4 | not present |
| Example 3 | 108.1 | 10 | 1.8 | not present |
| Example 4 | 98.6 | 15 | 0.4 | not present |
| Example 5 | 138.6 | 10 | 3.8 | not present |
| Example 6 | 149.4 | 10 | 4.8 | not present |
| Example 7 | 138.6 | 15 | 1.1 | not present |
| Comparison | 138.6 | 4.7 | 45.9 | present |
| example | | | | |

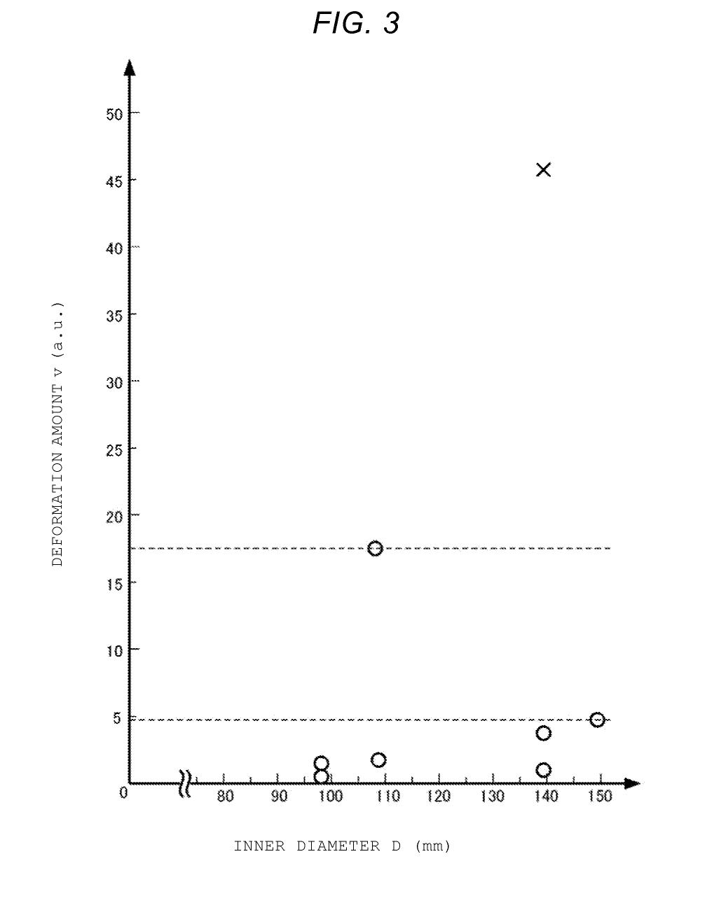

FIG. 3 is a graph showing test results for the examples 1-7 and the comparison example. An inner diameter D of the housing 12 is on the horizontal axis, and a deformation amount v of the housing 12 is on the vertical axis (the displayed units of the deformation amount are arbitrary as only relative differences between is examples is necessary for understanding). The deformation amount v is a value obtained by calculating the value of (2/5E)·(D/t)³. A circular mark in the graph indicates the cases where the housing 12 was not broken, while a mark “X” in the graph indicates the case where the housing was broken.

As may be clearly understood from Table 1 and FIG. 3, it is apparent that the explosion of the semiconductor device is suppressed when (2/5E)·(D/t)³ is 17.4 or less, that is, when the formula (1) is satisfied.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a frame body comprising ceramic and having an annular cylindrical shape, the frame body satisfying:
(2/5E)·(D/t)³≦17.4
where an inner diameter of the frame body is D (in mm), a thickness of the frame body in a radial direction is t (in mm), and the Young's modulus of the ceramic is E (in GPa);
a plurality of semiconductor elements disposed inside the frame body;
a first electrode block disposed on a first side of the plurality of semiconductor elements; and
a second electrode block disposed on a second side of the plurality of semiconductor elements, wherein
the plurality of semiconductor elements are enclosed within an interior space formed by at least the frame body, the first electrode block, and the second electrode block.

2. The semiconductor device according to claim 1, wherein the thickness of the frame body is 10 mm or more.

3. The semiconductor device according to claim 1, wherein the ceramic is alumina.

4. The semiconductor device according to claim 1, wherein the frame body satisfies the following:
(2/5E)·(D/t)³≦4.8.

5. The semiconductor device according claim 1, wherein the plurality of semiconductor elements includes an insulated gate bipolar transistor (IGBT).

6. The semiconductor device according claim 1, wherein the plurality of semiconductor elements includes a fast recovery diode (FRD).

7. The semiconductor device according to claim 1, further comprising:
a first flange connected to the first electrode block and the frame body; and
a second flange connected to the second electrode block and the frame body.

8. The semiconductor device according to claim 1, wherein the interior space is filled with an inert gas.

9. The semiconductor device according to claim 1, wherein the frame body includes an exterior ridge projecting outwardly from the frame body in the radial direction.

10. The semiconductor device according to claim 1, further comprising:
a first heat compensation plate within the interior space and between the first electrode block and the plurality of semiconductor elements;
a second heat compensation plate within the interior space and between the second electrode block and the plurality of semiconductor elements;
a resin frame within the interior space and supporting the plurality of semiconductor elements;
a first flange welded to the first electrode block and joined to the frame body by brazing; and
a second flange welded to the second electrode block and joined to the frame body by brazing.

11. A pressure contact type semiconductor device, comprising:
a semiconductor element hermetically sealed within in an interior space formed by:
a frame body,
a first electrode block on a first side of the semiconductor element,
a second electrode block on a second side of the semiconductor element,
a first flange joined to the frame body and the first electrode block, and
a second flange joined to the frame body and the second electrode block;
the frame body comprising ceramic and having an annular cylindrical shape that satisfies:
(2/5E)·(D/t)³≦17.4
where an inner diameter of the frame body is D (in mm), a thickness of the frame body in a radial direction is t (in mm), and the Young's modulus of the ceramic is E (in GPa).

12. The pressure contact type semiconductor device of claim 11, wherein the annular cylindrical shape of the frame body satisfies:
(2/5E)·(D/t)³≦4.8.

13. The pressure contact type semiconductor device of claim 11, wherein the ceramic is alumina, the first electrode block is copper, the second electrode block is copper, the first flange is nickel-iron alloy, and the second flange is nickel-iron alloy.

14. The pressure contact type semiconductor device of claim 11, wherein the semiconductor element is an insulated gate bipolar transistor (IGBT).

15. A method, comprising:
forming a frame body comprising ceramic and having an annular cylindrical shape that satisfies:
(2/5E)·(D/t)³≦17.4
where an inner diameter of the frame body is D (in mm), a thickness of the frame body in a radial direction is t (in mm), and Young's modulus of the ceramic is E (in GPa); and
enclosing a plurality of semiconductor elements in an interior space formed by at least the frame body, a first electrode block on a first side of the plurality of semiconductor elements, and a second electrode block on a second side of the plurality of semiconductor elements.

16. The method of claim 15, further comprising:
filling the interior space with an inert gas.

17. The method of claim 15, wherein enclosing the plurality of semiconductor elements in the interior space comprises:
welding the first electrode block to a first flange;
joining the first flange to the frame body by brazing;
welding the second electrode block to a second flange; and
joining the second flange to the frame body by brazing.

18. The method of claim 15, wherein the ceramic is alumina.

19. The method of claim 15, wherein the annular cylindrical shape of the frame body satisfies:
(2/5E)·(D/t)³≦4.8.

20. The method of claim 15, wherein the plurality of semiconductor elements includes an insulated gate bipolar transistor.
